(19) United States
(12) Patent Application Publication
(10) Pub. No.: US 2015/0208499 A1
(43) Pub. Date: Jul. 23, 2015

(54) CERAMIC CIRCUIT BOARD OF LASER PLATE COPPER AND MANUFACTURING METHOD THEREOF

(71) Applicant: Rhema Technology & Trading Company Limited, Seri Begawan (BN)

(72) Inventor: Ku Chou Wu, New Taipei City (TW)

(21) Appl. No.: 14/600,012

(22) Filed: Jan. 20, 2015

(30) Foreign Application Priority Data
Jan. 20, 2014 (TW) 103101966

(51) Int. Cl. H05K 1/03; H05K 1/09; H05K 1/02; H05K 3/10

(52) U.S. Cl. CPC H05K 1/0306; H05K 3/107; H05K 1/09; H05K 1/0284; H05K 2203/107; H05K 2203/12; H05K 2201/10106; H05K 2201/09036

(57) ABSTRACT

A ceramic circuit board of laser plate copper and manufacturing method thereof is provided. The method includes: providing a ceramic substrate; laser engraving, on a surface of the ceramic substrate, so as to form a circuit pattern of a plurality of groove structures; roughening and activating, on the surface of the ceramic substrate, by washing the surface of the ceramic substrate with a roughening and activating solution; and plating a metal layer, on the groove structures, so as to form a conductive loop defined by the circuit pattern.

### CROSS-REFERENCE TO RELATED APPLICATIONS

This non-provisional application claims priority under 35 U.S.C. §119(a) on Taiwan Patent Application No. 103101966 filed Jan. 20, 2014, the contents of which are incorporated herein by reference in its entirety.

### BACKGROUND

1. Technical Field

The present disclosure relates to a ceramic circuit board and, more particularly, to a ceramic circuit board of laser plate copper (LPC) and manufacturing method thereof

2. Description of Related Art

There is a need to improve the manufacturing process of a ceramic circuit board in the art. The ceramic circuit board is suitably applied to high power devices, such as high-power power module products, high-power light-emitting diode (LED) illumination products, and high-power high-frequency microwave products. The ceramic circuit board adopts a ceramic substrate with efficient heat dissipation and high-current load capability, which enables it to withstand under harsh work environments with high abrasion and corrosion, thereby meeting various application requirements of products. Conventional manufacturing methods of ceramic boards primarily include the low-temperature co-fired ceramics (LTCC) process and the direct plated copper (DPC) process.

In the LTCC process, the line-width resolution is about 150 μm˜300 μm and the circuit accuracy level is 10%, but the circuit board made by the LTCC process cannot be applied to flip-chip packaging and the equipment cost through the process is in the midrange. The LTCC process has a long turnaround time in making sample circuits and changing design order, which adversely increases the manufacturing cost, and three-dimensional circuits can not be made through the LTCC process. Additionally, the ceramic substrate used in the process is usually included with 30%˜50% glass material to lower the sintering temperature during the process, making the thermal conductivity of the substrate to be about 2˜3 W/m° C., thus limiting the scope of the applications.

In the DPC process, on the other hand, the line-width resolution is better (at about 10 μm˜50 μm) and the circuit accuracy level is 1%. The circuit board made by the DPC process can be applied to flip-chip packaging. However, the equipment cost through the process is relatively expensive, and the DPC process also has a long turnaround time in making sample circuits and changing design order (typically for 1˜2 weeks), making the manufacturing cost expensive, and three-dimensional circuits cannot be made through the DPC process. Additionally, the DPC process requires a clean-room operation environment.

A laser engraving process in the ceramic circuit board manufacturing is also available. In the laser engraving process, a ceramic circuit board is made by first forming a circuit pattern by laser engraving and later plating with a metal layer. The laser engraving process has the characteristics: good line-width and line-space (at about 80 μm˜100 μm); circuit accuracy level of 1%; circuit boards suitable for flip-chip packaging; relatively low in the equipment cost. Additionally, the circuit pattern is defined by the laser engraving pattern and requires no screen printing, and therefore, compared to the LTCC and DPC processes, the laser engraving process has many advantages, such as, relatively low manufacturing cost and suitable for making three-dimensional circuits, and among others.

However, in the manufacture using conventional laser engraving processes, the plating capability of the metal trace may not be good enough to attach securely to the surface of the ceramic circuit board and result in pilling effect. Moreover, the surface-mounted device (SMD) process during the manufacture of ceramic circuit board requires a high-temperature (at 260° C.˜290° C.) operation environment, which is also prone to causing the pilling effect on the metal trace. High percentage of pilling on the surface of the ceramic substrate further reduces the yield rate, durability, and productivity of the products.

### SUMMARY

To solve the aforementioned problems, the present disclosure provides a ceramic circuit board and manufacturing method thereof, and, in particular, provides a ceramic circuit board of laser plate copper that has high product yield and thus good for productivity.

A manufacturing method of a ceramic circuit board is provided. The method includes: providing a ceramic substrate; laser engraving, on a surface of the ceramic substrate, so as to form a circuit pattern of a plurality of groove structures; roughening and activating, on the surface of the ceramic substrate, by washing the surface of the ceramic substrate with a roughening and activating solution; and plating a metal layer, on the groove structures, so as to form a conductive loop defined by the circuit pattern.

A ceramic circuit board of laser plate copper is also provided and includes: a ceramic substrate including aluminum nitride or aluminum oxide, in which the weight percent of aluminum in the ceramic substrate including aluminum nitride ranges from 46 wt % to 55 wt %, and the weight percent of aluminum in the ceramic substrate including aluminum oxide ranges from 38 wt % to 48 wt %; a surface of the ceramic substrate including a circuit pattern formed by a plurality of groove structures by performing a laser engraving; and a metal layer, the metal layer being plated on the groove structures so as to form a conductive loop defined by the circuit pattern.

In one embodiment of this disclosure, the weight percent (wt %) of aluminum constituent of the ceramic substrate, prior to the laser engraving, is a first weight percent, and the weight percent of aluminum constituent of the ceramic substrate, after the laser engraving, is a second weight percent, with the second weight percent smaller than the first weight percent.

In one embodiment of this disclosure, further includes, after the roughening and activating and before the plating the metal layer, a step of annealing, by first increasing the temperature of the ceramic board to an initial temperature for annealing and then maintaining the initial temperature for a first period of time for annealing, followed by slowly cooling down the temperature of the ceramic board to room temperature.

In one embodiment of this disclosure, the initial temperature for annealing ranges from 250° C. to 600° C., and the first period of time for annealing ranges from 0.5 hrs to 3 hrs.

In one embodiment of this disclosure, the ceramic substrate is disposed on a heat sink during the laser engraving and the heat sink is ceramic or metal material.

In one embodiment of this disclosure, the circuit pattern is formed by a laser engraving with the laser of the wavelength ranging from 1 nm to 2 cm, in which the spot parameter of the laser is set to less than 150 μm and the power parameter of the laser is set to less than 200 watts.

In one embodiment of this disclosure, the circuit pattern is formed by the laser engraving with the infrared light of the wavelength ranging from 780 nm to 1400 nm, the green light of the wavelength ranging from 500 nm to 532 nm, or the ultraviolet light of the wavelength ranging from 200 nm to 400 nm.

In one embodiment of this disclosure, after the laser engraving, a bottom surface (i.e., the contact surface between the ceramic substrate and the metal layer) is exposed on the groove structures, of which the center line average roughness, the ten-point average roughness, and the roughness from the highest peak to the lowest valley of the surface roughness of the bottom surface range from 0.1 μm to 100 μm, from 1 μm to 100 μm, and from 2 μm to 80 μm, respectively.

In one embodiment of this disclosure, the average depth of the groove structures ranges from 1 μm to 80 μm.

In one embodiment of this disclosure, the cross-section of the contact surface between the ceramic substrate and the metal layer is a Gaussian distribution graph or a horizontal arrangement of multiple Gaussian distribution graphs.

In one embodiment of this disclosure, the roughening and activating solution includes Dipropylene glycol monomethyl ether and sodium metasilicate, in which the active temperature of the solution ranges from 20° C. to 100° C. and the active duration of the solution ranges from 1 min to 30 min.

In one embodiment of this disclosure, the concentration of Dipropylene glycol monomethyl ether in the solution ranges from 4% to 8% and the concentration of sodium metasilicate in the solution ranges from 1% to 3%, in which the active temperature of the solution ranges from 40° C. to 60° C. and the active duration of the solution ranges from 3 min to 10 min.

In one embodiment of this disclosure, the metal layer includes Au, Ag, Cu, Al, Mg, Fe, Ti, Ni, Pt, Pd, Sn, Zn, Cr, or a combination thereof

In one embodiment of this disclosure, the metal layer is sequentially formed to a copper-nickel-gold layer, a copper layer, a copper-nickel layer, a copper-nickel-silver layer, a copper-silver layer, a copper-tin layer, a copper-nickel-palladium-gold layer, or a copper-nickel-tin layer, using an electro-plating or an electroless plating.

In one embodiment of this disclosure, the circuit pattern is distributed on the surface of a certain plane, the surfaces of different planes, or the surface of the three-dimensional plane, of the ceramic substrate.

In one embodiment of this disclosure, the ceramic circuit board is applied to an LED illumination product, a 3C electronic product, a vehicle project, a medical product, or a ceramic antenna.

The advantageous effect of this disclosure is to improve the adhesive and plating quality between the ceramic substrate and the metal layer by controlling the amount of the aluminum constituent in the ceramic substrate, so as to increase the yield rate, as well as the durability and productivity, of the ceramic circuit board.

### BRIEF DESCRIPTION OF THE DRAWING

The characteristics as well as preferred modes of use, and advantages of the present disclosure will be best understood by referring to the following detailed description of some illustrative embodiments in conjunction with the accompanying drawing, in which:

FIG. 1 is a schematic view of a manufacturing method forming a ceramic circuit board of the present disclosure;

FIG. 2 is a flowchart of steps showing a manufacturing method forming a ceramic circuit board in accordance with an embodiment of the present disclosure;

FIG. 3 is a flowchart of steps showing a manufacturing method forming a ceramic circuit board in accordance with another embodiment of the present disclosure;

FIG. 4A is a curve graph of a Gaussian distribution formed by a bottom surface of groove structures in accordance with the present disclosure;

FIG. 4B is a schematic view of groove structures and the bottom surface in accordance with the present disclosure;

FIG. 5 is a schematic view of a construction showing a ceramic circuit board of laser plate copper in accordance with an embodiment of the present disclosure; and

FIG. 6 is a schematic view of a construction showing a ceramic circuit board of laser plate copper in accordance with another embodiment of the present disclosure.

### DETAILED DESCRIPTION OF THE PREFERRED EMBODIMENTS

In order to further understand the present disclosure, preferred embodiments are to be described such that variations and alterations thereto are readily apparent to a person skilled in the art. However, it will be realized that the scope of this disclosure is not confined or restricted to the details of the embodiments described below. Identical reference numerals always designate the same elements throughout all the figures of the drawing.

The present disclosure provides a ceramic circuit board of laser plate copper (LPC) comprising a ceramic substrate and a metal layer. The surface of the ceramic substrate includes a circuit pattern composed of multiple groove structures of laser plate copper, in which the amount of the aluminum constituent in the ceramic substrate ranges from 35 wt % to 55 wt %. The metal layer is plated on the groove structures to form the conductive loop defined by the circuit pattern.

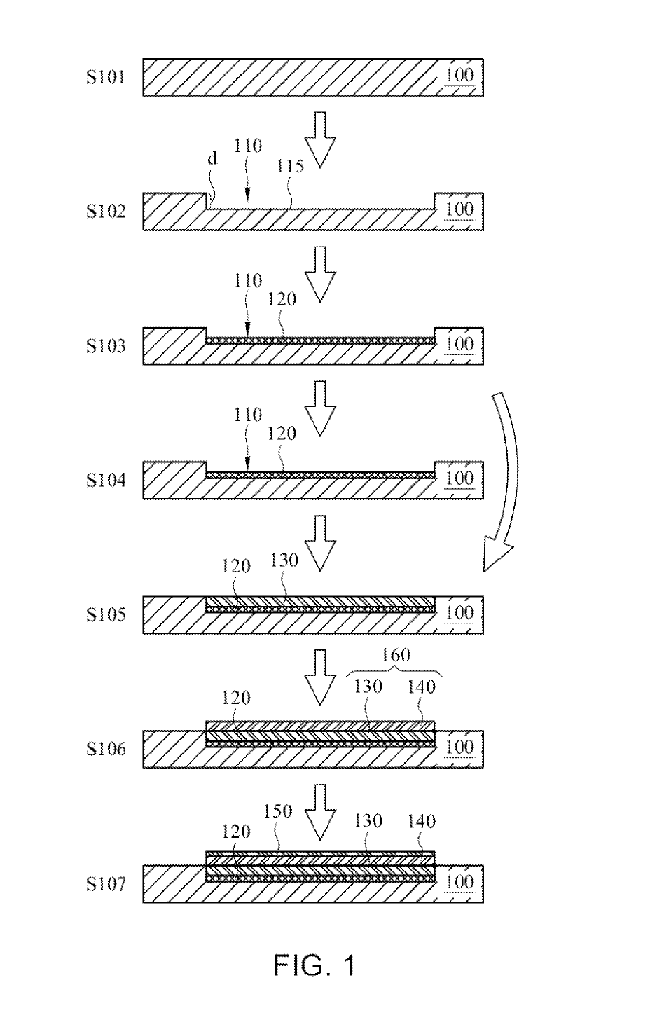

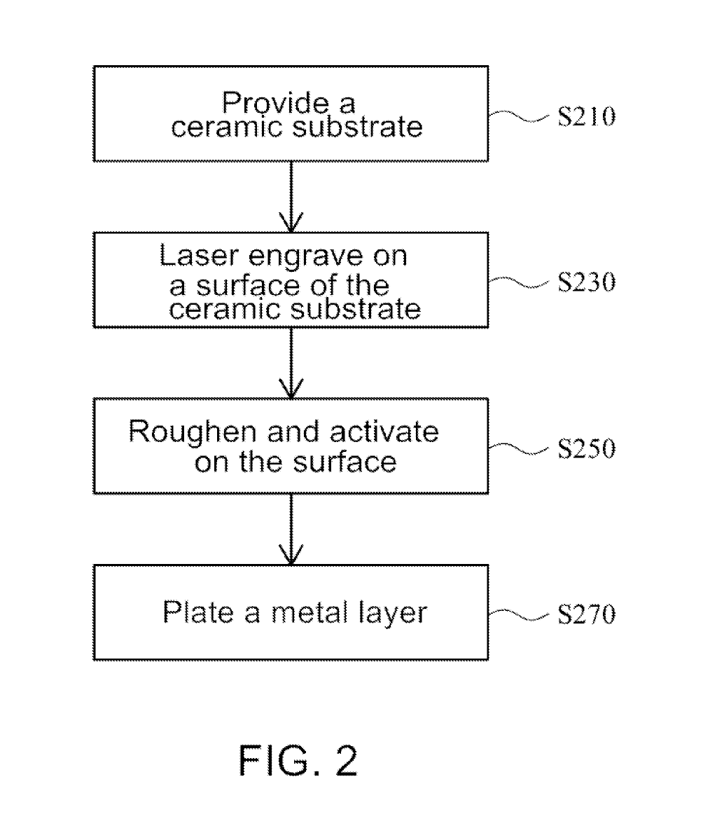

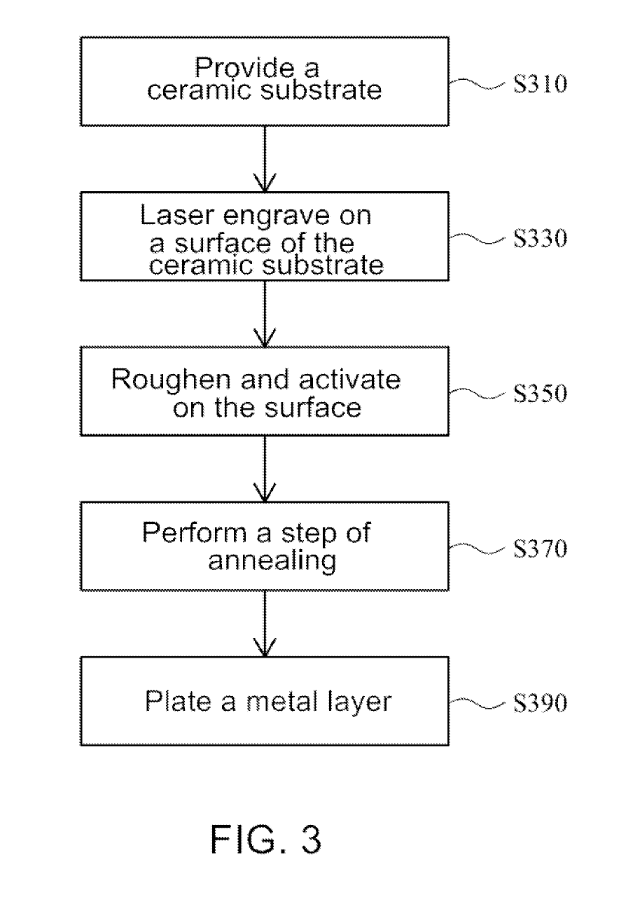

FIG. 1 shows a schematic view of a manufacturing method making a ceramic circuit board by using the LPC technique of the present disclosure. FIG. 2 is a flowchart of steps showing a manufacturing method forming a ceramic circuit board in accordance with an embodiment of the present disclosure. FIG. 3 is a flowchart of steps showing a manufacturing method forming a ceramic circuit board in accordance with another embodiment of the present disclosure. FIGS. 1-3 are described altogether as follows.

The step at S101 includes providing a suitable substrate (e.g., the step at S210 of FIG. 2 and the step at S310 of FIG. 3). The substrate may be a ceramic material, which includes, for example, aluminum oxide, aluminum nitride, silicon carbide, silicon nitride, beryllium oxide, zirconium dioxide, chromium (III) oxide, titanium dioxide, glass ceramic, aluminum titanate, and among others. As described herein, the substrate material is the ceramic substrate 100 having aluminum oxide or aluminum nitride, and, by controlling the weight percent of the aluminum constituent in the substrate, a better adhesion is achieved between the substrate and the metal layer, after the substrate has been laser engraved and the surface of the substrate has been roughened and activated, a process which prevents from pilling, lowers the possibility of the metal layer releasing from the substrate, and increases the plating capability, thereby improving product yield rate and thus productivity.

As can be seen in FIG. 1, the step at S102 includes laser engraving (e.g., the step at S230 of FIG. 2 and the step at S330 of FIG. 3). The laser engraving is performed on the surface of the ceramic substrate 100 based on a predetermined circuit pattern, so as to form the circuit pattern (110) composed of multiple groove structures 110. In the laser engraving, the laser wavelength ranges from 1 nm to 2 mm, in which, for example, the primarily used laser, such as infrared light with the wavelength ranging from 780 nm to 1400 nm, green light with the wavelength ranging from 500 nm to 532 nm, or ultraviolet light with the wavelength ranging from 200 nm to 400 nm, may be used, and the spot parameter of laser is set to less than 150 μm and the power parameter of laser is set to less than 200 watts.

Additionally, the ceramic substrate 100 may be disposed on a heat sink (not shown) when performing the laser engraving during the step of laser engraving at S102, in which the material of the heat sink may be graphite or metal. During laser engraving, a large amount of heat will be instantly accumulated in the local area of the ceramic substrate 100, and therefore, if the heat dissipation of the ceramic substrate is not sufficiently efficient, the mass-accumulated heat can cause the ceramic substrate 100 to burn black partially or completely, which most likely will cause overflow plating layer at the step of plating of metal layers, thus resulting in defect in manufacturing the ceramic circuit board.

After the circuit pattern (110) is formed on the ceramic substrate 100 by laser engraving based on the parameters described herein, a significant change occurs in the aluminum constituent in the ceramic substrate 100, and it is the amount of the aluminum constituent that has a substantial effect on the result of surface roughing and activating later in the process, on the adhesion and plating quality between the ceramic substrate 100 and the metal layer, and on the product yield rate and productivity. To sum up, if the weight percent of the aluminum constituent of the ceramic substrate 100 is a first weight percent prior to the laser engraving and the weight percent of the aluminum constituent of the ceramic substrate 100 is a second weight percent after the laser engraving, then the second weight percent will be less than the first weight percent. It has been verified by experiments that an energy dispersive spectrometer (EDS), for example, can be used to run an analysis on the amount of the aluminum constituent in the ceramic substrate 100, in order to achieve a better yield rate. Specifically, for the ceramic substrate 100 having the aluminum nitride material, if the amount of the aluminum constituent ranges from 50 wt % to 80 wt % prior to the laser engraving, then the amount of the aluminum constituent ranges from 46 wt % to 55 wt % after the laser engraving, and for the ceramic substrate 100 having the aluminum oxide material, if the amount of the aluminum constituent ranges from 40 wt % to 70 wt % prior to the laser engraving, then the amount of the aluminum constituent ranges from 38 wt % to 48 wt % after the laser engraving.

Additionally, after the circuit pattern, which is composed of multiple groove structures 110, is formed on the ceramic substrate by laser engraving, a bottom surface 115 (i.e., a contact surface between the ceramic substrate and the metal layer in the ceramic circuit board product) is exposed on the groove structures 110. It has been verified by experiments that certain surface roughness of the contact surface, if used in the process, can improve the product yield rate. Specifically, for the bottom surface 115 (i.e., the contact surface between the ceramic substrate and the metal layer), the center line average roughness, the ten-point average roughness, and the roughness from the highest peak to the lowest valley of the surface roughness range from 0.1 μm to 100 μm, from 1 μm to 100 μm, and from 2 μm to 80 μm, respectively. Moreover, the average depth of the groove structures 110 (i.e., the d of FIG. 1), when ranging from 1 μm to 80 μm, can also achieve better product yield rate and productivity.

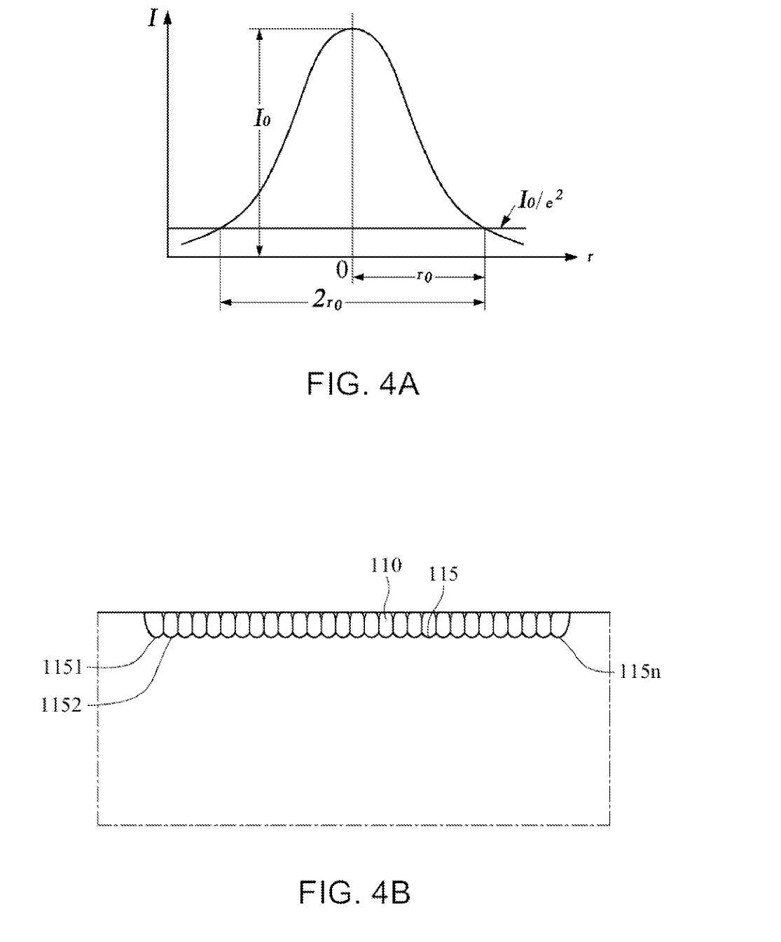

Furthermore, after the laser engraving with exemplary laser parameters disclosed herein, a Gaussian distribution graph, or a horizontal arrangement of multiple Gaussian distribution graphs, will be formed on the bottom surface 115 (i.e., a cross-section of the contact surface between the ceramic substrate 100 and the metal layer) of the groove structures 110. FIG. 4A is a curve graph of a Gaussian distribution formed by a bottom surface of groove structures in accordance with the present disclosure. As can be seen in the figure, the Gaussian distribution graph is a curve of bilateral symmetry. Assume that, in FIG. 4A, the variable of the horizontal axis (i.e., the x-axis) is r and the variable of the vertical axis (i.e., the y-axis) is I, and when r is 0 (zero), the curve has the maximum value of Iₒ, and when r is +/−rₒ, the curve has a value of Iₒ/e², then the function for the curve of Gaussian distribution can be denoted by Eqn. (1):

$$I = {I}_{0} {e}^{- ( \frac{2 {r}^{2}}{{r}_{0}^{2}} )} , \qquad ( 1 )$$

where e is Euler number

FIG. 4B is a schematic view showing the groove structures 110 and the bottom surface 115, in which each of the curves 1151, 1152, . . . , 115n is a curve having a Gaussian distribution characteristic and the bottom surface 115 is the horizontal arrangement of respective curves of Gaussian distribution 1151, 1152, . . . , 115n.

The step at S103 includes roughening and activating on the surface of the ceramic substrate (e.g., the step at S250 of FIG. 2 and the step at S350 of FIG. 3). For the roughening and activating, a roughening and activating solution is used to wash the surface of the ceramic substrate and the groove structures 110 after the step of the laser engraving. The roughing and activating solution contains two effective constituents, Dipropylene glycol monomethyl ether and sodium metasilicate, in which the concentration of Dipropylene glycol monomethyl ether ranges from 4% to 8% and the concentration of sodium metasilicate ranges from 1% to 3%. The pH value of the solution ranges from pH 8 to pH 12. The active temperature of the solution ranges from 20° C. to 100° C., preferably, from 40 ° C. to 60° C., and the active duration of the solution ranges from 1 min to 30 min, preferably, from 3 min to 10 min. The step of roughening and activating on the surface removes the smears and dusts on the exposed material so that an optimized roughened and activated surface 120 can be formed after activating the bottom surface 115 of the groove structures 110. Therefore, later in the process, metal ions in the chemical solution can be quickly plated on the roughened and activated surface 120 so as for the metal layer to facilitate adhesion capability.

The step at S104 includes annealing (e.g., the step at S370 of FIG. 3). In the step of annealing, the temperature of the ceramic substrate 100 is first raised to an initial temperature for annealing, and then the initial temperature is maintained for a first period of time for annealing, followed by cooling down the ceramic substrate 100 to room temperature, in which the initial temperature for annealing ranges from 250° C. to 600° C. and the first period of time for annealing ranges from 0.5 hrs to 3 hrs. The annealing process helps maintain the surface quality of the ceramic substrate 100, which would have otherwise been affected due to the process steps (e.g., laser engraving) applied on the ceramic substrate 100 at ambient temperature, and also helps increase the flexibility, ductility, and toughness of the ceramic substrate 100, release the residual stress therein, and produce specific microstructures. During the annealing, the residual stress of the ceramic substrate 100 is released by the displacement of atoms or lattice vacancy, and the structure dislocation of the ceramic substrate 100 is then removed through the process of atomic rearrangement. The annealing also facilitates the displacement of structural dislocation of the ceramic substrate 100, thus increasing the ductility of the ceramic substrate 100. Therefore, the annealing process makes better the surface quality of the ceramic substrate 100 suitable for the later metal plating process.

However, the annealing process is optional if there is a concern about the time required for annealing and the cost for related instruments. In such embodiment (i.e., the step S270 of plating a metal layer takes place right after completing the step S250 of roughening and activating the surface of the ceramic substrate), the product yield rate may be suboptimal.

Next, as can be seen in FIG. 1, the step at S105 includes plating copper, nickel, and gold (e.g., the step at S270 of FIG. 2 and the step at S390 of FIG. 3), in which a metal layer 160 is plated on the groove structures 110 to form a conductive loop defined by the circuit pattern (110). In one embodiment of this disclosure, copper metal is selected as the bottom layer of the metal layer 160 because the metal copper has the characteristics of easy activation and efficient electrical and thermal conductivity. By immersing the ceramic substrate 100 in a copper-containing chemical solution, a copper conductive layer 130 is formed by plating copper ions in the solution on the roughened bottom surface 120 using eletroless plating or electro-plating. The ideal thickness of the copper conductive layer 130 ranges from 3 μm to 25 μm. The ceramic substrate 100 can be, after being plated with the copper conductive layer 130, further processed, such as with well-known micro-etching process, to enhance the surface verticality of the copper conductive layer 130, and therefore optimize the surface quality.

Since the copper conductive layer 130 is prone to oxidize, metal such as nickel or silver can be further plated using electroless plating or electro-plating, to prevent the copper conductive layer 130 from oxidation. In this exemplary embodiment, metal nickel is plated for illustration. Plating nickle on the copper conductive layer 130 further provides corrosion resistance and increases hardness. Since the activation of copper is lower than that of nickel, prior to plating nickel, the copper layer needs to be activated (i.e., performing activation on the surface of the copper conductive layer 130 so as to induce metal nickel to deposit on the surface of the copper conductive layer 130). In the activation process of copper conductive layer 130, Palladium (Pd) or Ruthenium (Ru) can be used as a catalytic seed layer, and the process is known to those skilled in the art without further description.

Once the activation of the copper conductive layer 130 is completed, the step of electroless plating of nickel takes place. In addition, the more the amount of phosphor in the nickel plating layer is, the higher the corrosion resistance of nickel; therefore, phosphor can be added in the reducing agent such that phosphor and nickel co-deposit. Based on the amount of phosphor, there are typically three combinations with respect to the nickel in the nickel plating layer: low phosphorous nickel (phosphor ranging from 1% to 5%), medium phosphorous nickel (phosphor ranging from 6% to 9%, which is for 3C products), and high phosphorous nickel (phosphor ranging more than (>) 10%, which is for vehicle electronics). The nickel conductive layer 140 is formed after the process of nickel plating, and the ideal thickness of the layer is 2 μm to 30 μm.

After the nickel conductive layer 140 is formed (i.e., the metal layer 160 is made), the surface of the circuit board can be cleaned with dehydrating agent so that the water droplets on the surface can be quickly dissolved. The cleaning process also has the following advantages: greatly reducing the time and heat required for drying up the surface; removing water stains on the surface to reduce the effort required for drying piece by piece; and increasing the lubricity and salt-spray resistance of the plating surface. The ceramic circuit board is accordingly manufactured after a drying process.

Moreover, during the process of manufacturing and storage, the nickel conductive layer 140 is relatively prone to be oxidized and black nickel may be produced as an unreliable soldering spot after plating, and thus a gold conductive layer 150 may be formed on the nickel conductive layer 140. The gold conductive layer 150 has the characteristics of oxidation resistance, good electrical performance, low contact resistance, and easy solderability. The step of plating gold in the embodiment is illustrated in FIG. 1. The gold conductive layer can be formed by electroless plating or electro-plating, and the process is also well known to those skilled in the art without further description. After the gold conductive layer 150 is formed, the ceramic circuit board is accordingly manufactured by cleaning with dehydrating agent and drying process discussed above.

It should be noted that after the ceramic circuit board is made, if an analysis using the EDS is performed on the constituents, such as removing the metal layer 160 of the ceramic substrate 100, which is primarily composed of aluminum oxide or aluminum nitride, then the amount of the aluminum constituent still maintains the weight percent after the laser engraving. That is, for an aluminum nitride containing ceramic substrate 100, the amount of the aluminum constituent still maintains at the range of 46 wt %˜55 wt %, and for an aluminum oxide containing ceramic substrate 100, the amount of aluminum constituent still maintains at the range of 38 wt %˜48 wt %. This observation is one of the important technical features of the present disclosure. In other embodiments that use different materials in the ceramic circuit board, one can identify the primary constituent and its range of amount as an indicator of product yield rate, and the method should be readily understood and can be implemented by those skilled in the art after being fully appreciated the disclosure herein.

Furthermore, the metal layer 160 in the embodiment described above is plated by lamination. The metal layer 160 is formed, or sequentially formed, to copper layer, copper-nickel copper, and copper-nickel-gold layer. Alternatively, the metal layer may be formed to, for example, copper-nickel-silver layer, copper-silver layer, or copper-tin layer. More broadly, as it is well known to those skilled in the art, the metal layer may contain Au, Ag, Cu, Al, Mg, Fe, Ti, Ni, Pt, Pd, Sn, Zn, Cr, or a combination thereof.

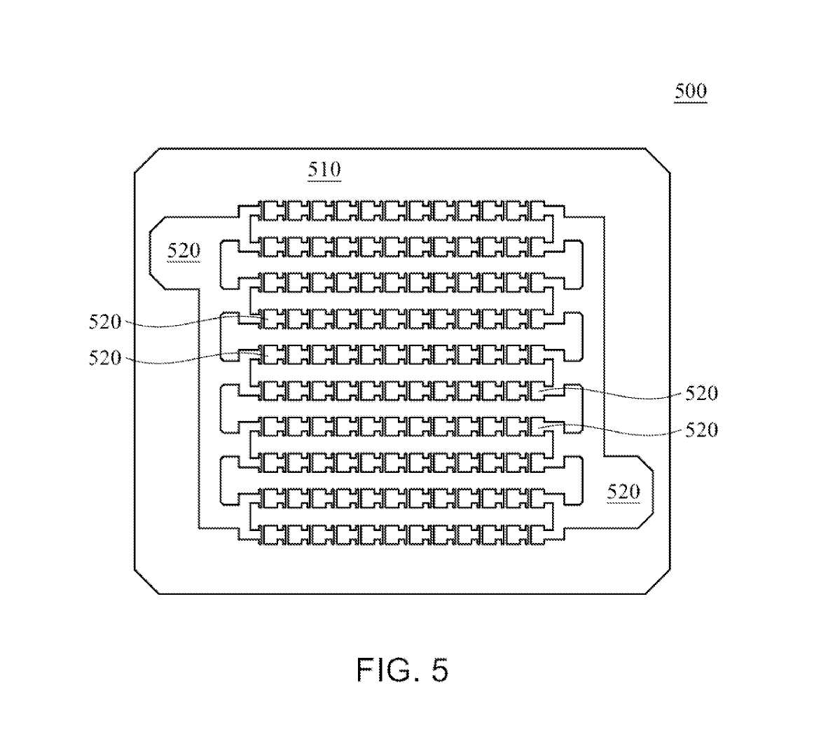

The ceramic circuit board of laser plate copper (LPC) described herein is manufactured using the LPC technology, and therefore the circuit pattern can be distributed on the surface of a certain plane, the surfaces of different planes, or the surface of a three-dimensional plane, of the ceramic substrate. The ceramic circuit board is suitable for various applications, such as the manufacture of circuit boards or elements used in LED illumination products, 3C electronics product, vehicle products, medical products or ceramic antenna. FIG. 5 shows a schematic view of a construction of a ceramic circuit board of LPC in accordance with an embodiment of the present disclosure. The ceramic circuit board 500 illustrated in the figure is applied to the LED illumination products and includes a ceramic substrate S10 and a metal layer S20. The ceramic substrate S10 may be a ceramic material primarily containing aluminum nitride. Because aluminum nitride has an efficient thermal conductivity (of about 270˜320 W/m° C., compared to a typical printed circuit board of about 0.3 W/m° C.), it can be applied to high-power LED illumination devices by lowering the work temperature of LED, thereby extending the service life of the LED element. The patterns constructed by the set of the metal layer S20 form the circuit pattern. Since the ceramic circuit board 500 is applied to the formation of the LED circuit, the circuit pattern is distributed on the surface of the same plane with respect to the ceramic substrate S10 (i.e., at the light section of the LED element).

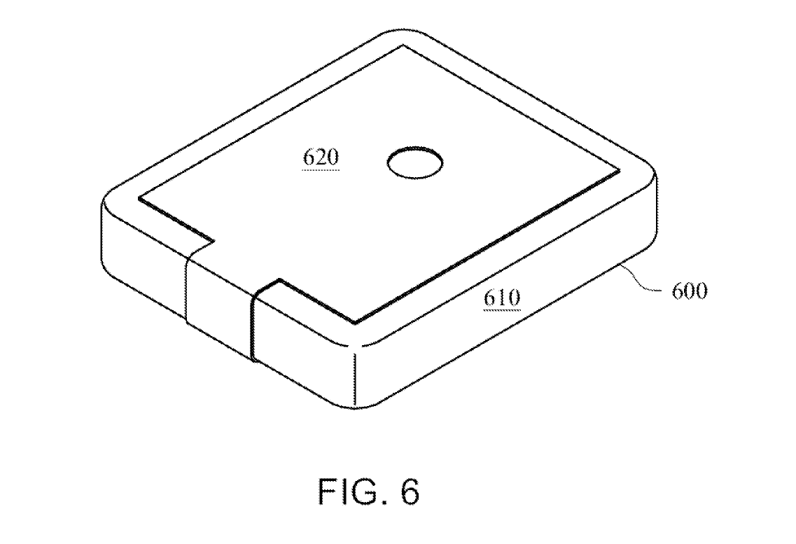

FIG. 6 shows a schematic view of a construction of a ceramic circuit board of LPC in accordance with another embodiment of the present disclosure. The ceramic circuit board 600 illustrated in the figure is applied to a ceramic antenna and includes a ceramic substrate 610 and a metal layer 620. The ceramic substrate 610 may be a ceramic material primarily containing aluminum nitride. Because aluminum nitride has characteristics of low coefficient of thermal expansion and proper dielectric constant (about 9), it can be applied to ceramic antenna by reducing the form factor of the antenna, and thus facilitating micromation of the antenna. The patterns constructed by the set of the metal layer 620 form the circuit pattern, and the circuit pattern is distributed on the surface of the different planes, or the surface of the three-dimensional plane, with respect to the ceramic substrate 610. For example, in FIG. 6, the metal layer 620 is mainly distributed on the upper plane and the left side plane with respect to the ceramic substrate 610, and the metal layer 620 is well implemented on the three-dimensional surface at the bonding areas of the upper plane and the left side plane. Additionally, since the circuit pattern of the ceramic circuit board 600 is defined by the pattern formed by the laser engraving during the manufacturing process, the ceramic circuit board 600 has the characteristics of high design flexibility and relatively lower time required for change order and cost, making it suitable for versatile applications such as antenna design, which illustrates one of technical advantages for the ceramic circuit board of LPC.

The present disclosure has been described by reference to the preferred embodiments thereof, and it is understood that the embodiments are not intended to limit the scope of the present disclosure. Moreover, as the contents disclosed herein should be readily understood and can be implemented by those skilled in the art, all equivalent changes or modifications which do not depart from the spirit of the present disclosure should be encompassed by the appended claims.

What is claimed is:

1. A manufacturing method of a ceramic circuit board of laser plate copper, comprising:
providing a ceramic substrate;
laser engraving, on a surface of the ceramic substrate, so as to form a circuit pattern of a plurality of groove structures;
roughening and activating, on the surface of the ceramic substrate, by washing the surface of the ceramic substrate with a roughening and activating solution; and
plating a metal layer, on the groove structures, so as to form a conductive loop defined by the circuit pattern.

2. The manufacturing method of claim 1, wherein the weight percent (wt %) of aluminum constituent of the ceramic substrate, prior to the laser engraving, is a first weight percent, and the weight percent of aluminum constituent of the ceramic substrate, after the laser engraving, is a second weight percent, with the second weight percent smaller than the first weight percent.

3. The manufacturing method of claim 2, wherein the ceramic substrate includes aluminum nitride or aluminum oxide, and wherein the first weight percent of the ceramic substrate including aluminum nitride ranges from 50 wt % to 80 wt % and the second weight percent of that ranges from 46 wt % to 55 wt %, and wherein the first weight percent of the ceramic substrate including aluminum oxide ranges from 40 wt % to 70 wt % and the second weight percent of that ranges from 38 wt % to 48 wt %.

4. The manufacturing method of claim 1, further comprising, after the roughening and activating, a step of annealing, by first increasing the temperature of the ceramic board to an initial temperature for annealing and then maintaining the initial temperature for a first period of time for annealing, followed by slowly cooling down the temperature of the ceramic board to room temperature.

5. The manufacturing method of claim 4, wherein the ceramic substrate is disposed on a heat sink during the laser engraving and the heat sink is a ceramic or a metal material.

6. The manufacturing method of claim 4, wherein the roughening and activating solution includes Dipropylene glycol monomethyl ether and sodium metasilicate, with the active temperature of the solution ranging from 20° C. to 100° C. and the active duration of the solution ranging from 1 min to 30 min.

7. A ceramic circuit board of laser plate copper, comprising:
a ceramic substrate including aluminum nitride or aluminum oxide, wherein the weight percent of aluminum in the ceramic substrate including aluminum nitride ranges from 46 wt % to 55 wt %, the weight percent of aluminum in the ceramic substrate including aluminum oxide ranges from 38 wt % to 48 wt %, a surface of the ceramic substrate including a circuit pattern formed by a plurality of groove structures by performing a laser engraving; and
a metal layer, the metal layer being plated on the groove structures so as to form a conductive loop defined by the circuit pattern.

8. The ceramic circuit board of claim 7, wherein there exists a contact surface between the ceramic substrate and the metal layer, the surface roughness of the contact surface has a center line average roughness ranging from 0.1 μm to 100 μm, a ten-point average roughness ranging from 1 μm to 100 μm, and a roughness from the highest peak to the lowest valley ranging from 2 μm to 80 μm.

9. The ceramic circuit board of claim 8, wherein the cross-section of the contact surface is a Gaussian distribution graph or a horizontal arrangement of multiple Gaussian distribution graphs.

10. The ceramic circuit board of claim 7, wherein the average depth of the groove structures ranges from 1 μm to 80 μm.

11. The ceramic circuit board of claim 7, wherein the circuit pattern is formed by the laser engraving with the infrared light of the wavelength ranging from 780 nm to 1400 nm, the green light of the wavelength ranging from 500 nm to 532 nm, or the ultraviolet light of the wavelength ranging from 200 nm to 400 nm.

12. The ceramic circuit board of claim 7, wherein the metal layer includes Au, Ag, Cu, Al, Mg, Fe, Ti, Ni, Pt, Pd, Sn, Zn, Cr, or a combination thereof.

13. The ceramic circuit board of claim 7, wherein the metal layer is sequentially formed to a copper-nickel-gold layer, a copper layer, a copper-nickel layer, a copper-nickel-silver layer, a copper-silver layer, a copper-tin layer, a copper-nickel-palladium-gold layer, or a copper-nickel-tin layer, using an electro-plating or an electroless plating.

14. The ceramic circuit board of claim 7, wherein the circuit pattern is distributed on the surface of a certain plane, the surfaces of different planes, or the surface of a three-dimensional plane, of the ceramic substrate.

15. The ceramic circuit board of claim 7, wherein the ceramic circuit board is applied to an LED illumination device or a ceramic antenna.
